(19) United States
(12) Patent Application Publication
(10) Pub. No.: US 2025/0101303 A1
(43) Pub. Date: Mar. 27, 2025

(54) ETCHING COMPOSITIONS

(71) Applicant: Fujifilm Electronic Materials U.S.A., Inc., N. Kingstown, RI (US)

(72) Inventors: Jieying Jiao, Chandler, AZ (US); Dmitry Dinega, Mesa, AZ (US); Thomas Dory, Gilbert, AZ (US)

(21) Appl. No.: 18/888,714

(22) Filed: Sep. 18, 2024

Related U.S. Application Data
(60) Provisional application No. 63/539,609, filed on Sep. 21, 2023.

(51) Int. Cl. C09K 13/00; H01L 21/02; H01L 21/3213

(52) U.S. Cl. CPC C09K 13/00; H01L 21/02068; H01L 21/32134

(57) ABSTRACT

The present disclosure is directed to etching compositions that are useful for, e.g., selectively removing silicon from a semiconductor substrate as an intermediate step in a multistep semiconductor manufacturing process.

### CROSS-REFERENCE TO RELATED APPLICATION

The present application claims priority to U.S. Provisional Application Ser. No. 63/539,609, filed on Sep. 21, 2023, the contents of which are hereby incorporated by reference in their entirety.

### FIELD OF THE DISCLOSURE

The present disclosure relates to etching compositions and processes of using etching compositions. In particular, the present disclosure relates to etching compositions that can selectively etch silicon in the presence of other exposed or underlying materials, such as metal conductors (e.g., copper), gate materials (e.g., SiGe), barrier materials, insulator materials (e.g., low-k dielectric materials).

### BACKGROUND OF THE DISCLOSURE

The semiconductor industry is rapidly decreasing the dimensions and increasing the density of electronic circuitry and electronic components in microelectronic devices, silicon chips, memory chips, liquid crystal displays, MEMS (Micro Electro Mechanical Systems), printed wiring boards, and the like. The integrated circuits within them are being layered or stacked with insulating layers having constantly decreasing thicknesses between each circuitry layer. As the feature sizes have shrunk, patterns have become smaller, and device performance parameters tighter and more robust. As a result, various issues which heretofore could be tolerated can no longer be tolerated or have become more of an issue due to the smaller feature size.

In the production of advanced integrated circuits, to minimize problems associated with the higher density and to optimize performance, both high k and low k insulators, and assorted barrier layer materials have been employed.

Silicon (Si) can be utilized in the manufacturing of semiconductor devices, liquid crystal displays, MEMS (Micro Electro Mechanical Systems), printed wiring boards and the like. Silicon frequently needs to be removed in the presence of other exposed materials in a semiconductor substrate during an etching process.

### SUMMARY OF THE DISCLOSURE

In the construction of semiconductor devices, silicon (Si) frequently needs to be etched. In the various types of uses and device environment of Si, other layers are in contact with or otherwise exposed at the same time as this material is etched. Highly selective etching of the Si in the presence of these other materials (e.g. metal conductors, dielectrics, channel materials, gate materials, and hard masks) is typically needed for device yield and long life.

The present disclosure relates to compositions and processes for selectively etching Si (e.g., polysilicon) relative to hard mask layers, gate materials (e.g., SiGe, SiN, or SiOx) and/or low-k dielectric layers (e.g., SiN, SiOx, carbon doped oxide, or SiCO) that are present in the semiconductor device.

In some embodiments, the disclosure provides etching compositions including: at least one quaternary ammonium hydroxide;
at least one first amine;
at least one second amine different from the first amine, wherein the second amine includes an amine of formula (I): N—R₁R₂R₃, wherein R₁ is C₁-C₈ alkyl optionally substituted by OH or NH₂, R₂ is H or C₁-C₈ alkyl optionally substituted by OH, and R₃ is C₁-C₈ alkyl optionally substituted by OH;
at least one organic solvent selected from water soluble alcohols, water soluble ketones, water soluble esters, and water soluble ethers; and
water.

In some embodiments, the quaternary ammonium hydroxide includes tetramethylammonium hydroxide, tetraethylammonium hydroxide, or tetrabutylammonium hydroxide. In some embodiments, the quaternary ammonium hydroxide is in an amount of from about 1 wt % to about 15 wt % of the composition.

In some embodiments, the first amine is a diamine. In some embodiments, the diamine has a structure

NH₂—R—NH₂,
wherein R is a C₁ to C₁₀ straight chain or branched alkylene. Examples of amines contemplated as first amines include, but are not limited to, 1,5-diamino-2-pentane; 1,6-hexanediamine; trimethyl-1,6-hexanediamine; and 1,3-diaminopropane. In some embodiments, the diamine is 1,5-diamino-2-methylpentane. In some embodiments, the first amine is a triamine such as diethylenetriamine. In some embodiments, the first amine is in an amount of from about 10 wt % to about 40 wt % of the composition.

In some embodiments, the second amine is an aminoalcohol. In some embodiments, the second amine is in an amount of from about 0.01 wt % to about 0.5 wt % of the composition.

In some embodiments, the etching compositions of the disclosure further comprise at least one organophosphorus compound. In some embodiments, the organophosphorus compound is a phosphine, phosphite, phosphate, or phosphinamide. In some embodiments, the organophosphorus compound is a phosphinamide. In some embodiments, the phosphinamide is diphenylphosphinamide.

In some embodiments, the organophosphorus compound is in an amount of from about 0.01 wt % to about 0.5 wt % of the composition.

In some embodiments, the organic solvent is an alkylene glycol. In some embodiments, the alkylene glycol is ethylene glycol, propylene glycol, diethylene glycol, dipropylene glycol, triethylene glycol or tetraethyleneglycol.

In some embodiments, the organic solvent is an alkylene glycol ether. Examples of alkylene glycol ethers contemplated include, but are not limited to, ethylene glycol monomethyl ether, ethylene glycol monoethyl ether, ethylene glycol mono n-propyl ether, ethylene glycol monoisopropyl ether, ethylene glycol mono n-butyl ether, diethylene glycol monomethyl ether, diethylene glycol monoethyl ether, diethylene glycol monobutylether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

In some embodiments, the organic solvent is in an amount of from about 2 wt % to about 40 wt %.

In some embodiments, the compositions of the disclosure have a pH from about 11 to about 14.

In some embodiments, the water is in an amount of from about 25 wt % to about 80 wt % of the composition.

In some embodiments, the disclosure provides methods including:
contacting a semiconductor substrate containing a Si film with a composition of the disclosure to substantially remove the Si film.

In some embodiments, the methods do not substantially remove silicon oxide or silicon nitride.

In some embodiments, the disclosure provides articles formed by the methods of the disclosure. In some embodiments, the articles are semiconductor devices. In some embodiments, the articles are integrated circuits.

### DETAILED DESCRIPTION OF THE DISCLOSURE

As defined herein, unless otherwise noted, all percentages expressed should be understood to be percentages by weight to the total weight of the composition. Unless otherwise noted, ambient temperature is defined to be between about 16 and about 27 degrees Celsius (° C.). As used herein, the terms “layer” and “film” are used interchangeably.

In general, the disclosure features an etching composition (e.g., an etching composition for selectively removing Si) that includes (e.g., comprises or consists of) at least one quaternary ammonium hydroxide, at least one first amine, at least one second amine different from the first amine, wherein the second amine includes an amine of formula (I): N—R₁R₂R₃, wherein R₁ is C₁-C₈ alkyl optionally substituted by OH or NH₂, R₂ is H or C₁-C₈ alkyl optionally substituted by OH, and R₃ is C₁-C₈ alkyl optionally substituted by OH; at least one organic solvent selected from water soluble alcohols, water soluble ketones, water soluble esters, and water soluble ethers; and
water.

In some embodiments, the Si to be removed is amorphous silicon or polysilicon (poly-Si), such as doped poly-Si (e.g., n-type poly-Si or p-type poly-Si). The doped poly-Si can include a suitable dopant, such as phosphorus, boron, or other appropriate elements.

In some embodiments, the etching compositions of the disclosure can include at least one (e.g., two, three, or four) quaternary ammonium hydroxide(s). The quaternary ammonium hydroxide(s) described herein can be a tetraalkylammonium hydroxide, or the hydroxide anion of the quaternary ammonium hydroxide can be replaced with fluoride, chloride, or bromide. In some embodiments, each alkyl group in the tetraalkylammonium hydroxide, independently, is a C₁-C₁₈ alkyl optionally substituted by OH or aryl (e.g., phenyl). Examples of suitable tetraalkylammonium hydroxides include tetramethylammonium hydroxide (TMAH), tetraethylammonium hydroxide, tetrapropylammonium hydroxide, tetrabutylammonium hydroxide, benzyltrimethylammonium hydroxide (BTMAH), methyltriethylammonium hydroxide, ethyltrimethylammonium hydroxide (ETMAH), dimethyldiethylammonium hydroxide, 2-hydroxyethyltrimethylammonium hydroxide, tetraethanolammonium hydroxide, benzyltriethylammonium hydroxide, benzyltributylammonium hydroxide, and hexadecyltrimethylammonium hydroxide.

In some embodiments, the at least one quaternary ammonium hydroxide is in an amount of at least about 1 wt % (e.g., at least about 2 wt %, at least about 3 wt %, at least about 4 wt %, at least about 5 wt %, at least about 6 wt %, at least about 7 wt %, or at least about 8 wt %) to at most about 15 wt % (e.g., at most about 14 wt %, at most about 12 wt %, at most about 10 wt %, at most about 8 wt %, at most about 7 wt %, at most about 6 wt %, or at most about 5 wt %) of the etching composition of this disclosure. Without wishing to be bound by theory, it is believed that the quaternary ammonium hydroxide can facilitate and enhance the removal of Si on a semiconductor substrate during the etching process.

The etching compositions of the disclosure include a first amine. The first amine is not particularly limited and can include primary amines, secondary amines, and/or tertiary amines. In some embodiments, the primary amine is a C₁ to C₁₀ alkyl amine. In some embodiments, the secondary amine includes two C₁-C₁₀ alkyl moieties. In some embodiments, the tertiary amine includes three C₁-C₁₀ alkyl moieties. The amine can be a monoamine, a diamine, or a triamine.

In some embodiments, the first amine is a diamine. In some embodiments, the diamine has a structure

NH₂—R—NH₂,
wherein R is a C₁ to C₁₀ straight chain or branched alkylene. Examples of amines contemplated as first amines include, but are not limited to, 1,5-diamino-2-pentane; 1,6-hexanediamine; trimethyl-1,6-hexanediamine; and 1,3-diaminopropane. In some embodiments, the diamine is 1,5-diamino-2-methylpentane. In some embodiments, the first amine is a triamine such as diethylenetriamine.

In some embodiments, the first amine is in an amount of from about 10 wt % to about 40 wt % of the composition. In some embodiments, the at least one first amine can be present from about 2 wt % (e.g., at least about 3 wt %, at least about 4 wt %, at least about 5 wt %) to at most about 40 wt % (e.g., at most about 35 wt %, at most about 30 wt %, at most about 25 wt %, at most about 20 wt %, at most about 15 wt %) of the etching composition.

The etching compositions of the disclosure include a second amine different from the first amine, wherein the second amine includes an amine of formula (I): N—R₁R₂R₃, wherein R₁ is C₁-C₈ alkyl optionally substituted by OH or NH₂, R₂ is H or C₁-C₈ alkyl optionally substituted by OH, and R₃ is C₁-C₈ alkyl optionally substituted by OH.

In some embodiments, the second amine is an aminoalcohol. Examples of aminoalcohols contemplated include, but are not limited to, monoethanolamine, diethanolamine, triethanolamine, 4-amino-1-butanol, 2-(2-aminoethoxy) ethanol, 3-amino-1-propanol, 2-amino-1-propanol, 1-amino-2-propanol, 2-amino-1-butanol, 2-amino-2-methyl 1-propanol, 2-(2-aminoethoxy) propanol, 5-amino-1-pentanol, 2-amino-1-pentanol, 2-amino-3-methyl-1-butanol, 2-amino-1-hexanol, isoleucinol, leucinol, 1-amino-1-cyclopentanemethanol, trans-2-aminocyclohexanol, trans-4-aminocyclohexanol, 3-aminomethyl-3,5,5-trimethylcyclohexanol, 1-aminomethyl-1-cyclohexanol, 6-amino-1-hexanol, 6-amino-2-methyl-2-heptanol, 4-amino-4-(3-hydroxypropyl)-1,7-heptanediol, serinol, 3-amino-1,2-propanediol, N-(3-aminopropyl)-diethanolamine, 2-amino-2-ethyl-1,3-propanediol, 2-amino-2-methyl-1,3-propanediol, tris (hydroxymethyl)-aminomethane, 1-amino-1-deoxy-D-sorbitol, (hydroxyethoxyethyl) amine, 4-amino-1-butanol, 2-(2-aminoethoxy) ethanol, ethanolamine, 3-amino-1-propanol, 2-amino-1-propanol, 1-amino-2-propanol, 2-amino-1-butanol, 2-amino-2-methyl 1-propanol, 2-(2-aminoethoxy) propanol, 5-amino-1-pentanol, 2-amino-1-pentanol, 2-amino-3-methyl-1-butanol, 2-amino-1-hexanol, isoleucinol, leucinol, 1-amino-1-cyclopentanemethanol, trans-2-aminocyclohexanol, trans-4-aminocyclohexanol, 3-aminomethyl-3,5,5-trimethylcyclohexanol, 1-aminomethyl-1-cyclohexanol, 6-amino-1-hexanol, and 6-amino-2-methyl-2-heptanol.

The etching compositions of the disclosure can further include at least one organophosphorus compound. In some embodiments, the organophosphorus compound is a phosphine, phosphite, phosphate, or phosphinamide. In some embodiments, the organophosphorus compound is a phosphinamide. In some embodiments, the phosphinamide is diphenylphosphinamide.

In some embodiments, the organophosphorus compound is in an amount of from about 0.01 wt % to about 0.5 wt % of the composition.

In general, the etching compositions of this disclosure can include water as a solvent. In some embodiments, the water can be de-ionized and ultra-pure, contain no organic contaminants, and/or have a minimum resistivity of about 4 to about 17 mega Ohms or at least about 17 mega Ohms. In some embodiments, the water is in an amount of from at least about 25 wt % (e.g., at least about 30 wt %, at least about 35 wt %, at least about 45 wt %, at least about 55 wt %, at least about 60 wt %, at least about 65 wt %) to at most about 80 wt % (e.g., at most about 78 wt %, at most about 77 wt %, at most about 76 wt %, at most about 75 wt %, at most about 74 wt %, at most about 73 wt %, at most about 72 wt %, at most about 71 wt %) of the etching composition. Without wishing to be bound by theory, it is believed that, if the amount of water is greater than 80 wt % of the composition, it would adversely impact the Si etch rate, and reduce its removal during the etching process. On the other hand, without wishing to be bound by theory, it is believed that the etching composition of this disclosure should include a certain level of water (e.g., at least about 25 wt %) to avoid reduction in the etching performance.

The etching compositions of this disclosure include at least one (e.g., two, three, or four) organic solvent. In some embodiments, the organic solvent can be a water soluble organic solvent. As defined herein, a “water soluble” substance (e.g., a water soluble organic solvent) refers to a substance having a solubility of at least 1% by weight in water at 25° C. In some embodiments, the organic solvent can be selected from the group consisting of water soluble alcohols (e.g., alkane diols or glycols such as alkylene glycols), water soluble ketones, water soluble esters, and water soluble ethers (e.g., glycol ethers).

In some embodiments, the organic solvent is an alkylene glycol. In some embodiments, the alkylene glycol is ethylene glycol, propylene glycol, diethylene glycol, dipropylene glycol, triethylene glycol, or tetraethyleneglycol.

In some embodiments, the organic solvent is an alkylene glycol ether. Examples of alkylene glycol ethers contemplated include, but are not limited to, ethylene glycol monomethyl ether, ethylene glycol monoethyl ether, ethylene glycol mono n-propyl ether, ethylene glycol monoisopropyl ether, ethylene glycol mono n-butyl ether, diethylene glycol monomethyl ether, diethylene glycol monoethyl ether, diethylene glycol monobutylether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

In some embodiments, the at least one organic solvent can be from at least about 2 wt % (e.g., at least about 3 wt %, at least about 4 wt %, at least about 5 wt %) to at most about 40 wt % (e.g., at most about 35 wt %, at most about 30 wt %, at most about 25 wt %, at most about 20 wt %, at most about 15 wt %) of the etching composition. In some embodiments, the etching composition of this disclosure can be substantially free of an organic solvent.

In some embodiments, the etching composition of this disclosure can have a pH of at least about 11 (e.g., at least about 11.1, at least about 11.2, at least about 11.5, at least about 11.7, or at least about 12.0) to at most about 14 (e.g., at most about 13.9, at most about 13.8, at most about 13.7, at most about 13.6, or at most about 13.5). Without wishing to be bound by theory, it is believed that an etching composition having a pH lower than 11 or higher than 14 would not have a sufficient Si removal rate and/or a sufficient bath loading capacity.

In some embodiments, the cleaning compositions of this disclosure can optionally include at least one (e.g., two, three, or four) pH adjusting agent (e.g., an acid or a base) to control the pH to from about 11 to about 14. The amount of the pH adjusting agent required, if any, can vary as the concentrations of the other components (e.g., the quaternary ammonium hydroxide and the acid) are varied in different formulation. In some embodiments, the pH adjusting agent can be at least about 0.1 wt % (e.g., at least about 0.2 wt %, at least about 0.4 wt %, at least about 0.5 wt %, at least about 0.6 wt %, at least about 0.8 wt %, at least about 1 wt %, at least about 1.2 wt %, at least about 1.4 wt %, or at least about 1.5 wt %) and/or at most about 3 wt % (e.g., at most about 2.8 wt %, at most about 2.6 wt %, at most about 2.5 wt %, at most about 2.4 wt %, at most about 2.2 wt %, at most about 2 wt %, or at most about 1.8 wt %) of the etching composition. In some embodiments, the etching composition of this disclosure can be substantially free of a pH adjusting agent.

In some embodiments, the pH adjusting agent is free of any metal ion (except for a trace amount of metal ion impurities). Suitable metal ion free pH adjusting agents include acids and bases. Suitable acids that can be used as a pH adjusting agent include organic acids (e.g., carboxylic acids) and inorganic acids. Exemplary carboxylic acids include, but are not limited to, monocarboxylic acids, bicarboxylic acids, tricarboxylic acids, α-hydroxyacids and β-hydroxyacids of monocarboxylic acids, α-hydroxyacids or β-hydroxyacids of bicarboxylic acids, or α-hydroxyacids and β-hydroxyacids of tricarboxylic acids. Examples of suitable carboxylic acids include citric acid, maleic acid, fumaric acid, lactic acid, glycolic acid, oxalic acid, tartaric acid, succinic acid, and benzoic acid. Examples of suitable inorganic acids include phosphoric acid, nitric acid, sulfuric acid, and hydrochloric acid.

Suitable bases that can be used as a pH adjusting agent include ammonium hydroxide, monoamines (including alkanolamines), and cyclic amines. Examples of suitable monoamines include, but are not limited to, triethylamine, tributylamine, tripentylamine, diethylamine, butylamine, dibutylamine, and benzylamine. Examples of suitable alkanolamines include, but are not limited to, monoethanolamine, diethanolamine, triethanolamine, and aminopropyldiethanolamine. Examples of suitable cyclic amines include, but are not limited to, 1,8-diazabicyclo[5.4.0]-7-undecene (DBU), 1,5-diazabicyclo[4.3.0]-5-nonene (DBN), and octahydro-2H-quinolizine.

In some embodiments, the etching composition of the present disclosure can contain additives such as, pH adjusting agents, corrosion inhibitors, surfactants, additional organic solvents, biocides, and defoaming agents as optional components. Examples of certain suitable additives include alcohols (e.g., polyvinyl alcohol and sugar alcohols). Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants can be cationic, anionic, nonionic, and amphoteric surfactants.

In general, the etching composition of the present disclosure can have a relatively high Si/dielectric material (e.g., SiN, SiOx, or SiCO) removal rate selectivity (i.e., a high ratio of Si removal rate over dielectric material removal rate). In some embodiments, the etching composition can have a Si/dielectric material removal rate selectivity of at least about 10 (e.g., at least about 20, at least about 40, at least about 50, at least about 60, at least about 80, at least about 100, at least about 150, at least about 200, at least about 250, at least about 300, at least about 350, at least about 400, at least about 450, at least about 500, or at least about 1000) and/or at most about 5000 (e.g., at most about 4000, at most about 3000, at most about 2000, or at most about 1000).

In some embodiments, the etching compositions of the present disclosure can be substantially free of one or more of additive components, in any combination, if more than one. Such components are selected from the group consisting of organic solvents, polymers (e.g., non-ionic, cationic, or anionic polymers), oxygen scavengers, quaternary ammonium compounds (e.g., salts or hydroxides), alkaline bases (such as NaOH, KOH, LiOH, Mg (OH) 2, and Ca (OH) 2), surfactants (e.g., cationic, anionic, or non-ionic surfactants), defoamers, fluorine-containing compounds (e.g., fluoride compounds or fluorinated compounds (such as fluorinated polymers/surfactants)), silicon-containing compounds such as silanes (e.g., alkoxysilanes), nitrogen-containing compounds (e.g., amino acids, amines, imines (e.g., amidines such as 1,8-diazabicyclo[5.4.0]-7-undecene (DBU) and 1,5-diazabicyclo[4.3.0]non-5-ene (DBN)), amides, or imides), abrasives (e.g., ceria abrasives, non-ionic abrasives, surface modified abrasives, negatively/positively charged abrasive, or ceramic abrasive composites), plasticizers, oxidizing agents (e.g., peroxides such as hydrogen peroxide, and periodic acid), corrosion inhibitors (e.g., azole or non-azole corrosion inhibitors), electrolytes (e.g., polyelectrolytes), silicates, cyclic compounds (e.g., azoles (such as diazoles, triazoles, or tetrazoles), triazines, and cyclic compounds containing at least two rings such as substituted or unsubstituted naphthalenes, or substituted or unsubstituted biphenylethers), chelating agents, buffering agents, acids such as organic acids (e.g., carboxylic acids such as hydroxycarboxylic acids, polycarboxylic acids, and sulfonic acid) and inorganic acids (e.g., sulfuric acid, sulfurous acid, nitrous acid, nitric acid, phosphorous acid, and phosphoric acid), salts (e.g., halide salts or metal salts), and catalysts (e.g., metal-containing catalysts). In some embodiments, the composition is substantially free of a salt other than a quaternary ammonium salt. As used herein, a component that is “substantially free” from an etching composition refers to an ingredient that is not intentionally added into the etching composition. In some embodiments, the etching composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above components that are substantially free from the etching composition. In some embodiments, the etching compositions described herein can be completely free of one or more of the above components.

The etching composition of this disclosure can be prepared by simply mixing the components together, or can be prepared by blending two or more compositions (each containing certain components of an etching composition described herein) in a kit.

In some embodiments, the present disclosure features a method of etching a semiconductor substrate that includes a Si film (e.g., in a Si-containing feature). The method can include contacting a semiconductor substrate containing the Si film (e.g., a poly-Si film) with an etching composition of this disclosure to substantially remove the Si film. In some embodiments, the semiconductor substrate can include a pattern or a feature on a surface and the Si film is a part of the pattern or feature. In some embodiments, the method can further include rinsing the semiconductor substrate with a rinse solvent after the contacting step and/or drying the semiconductor substrate after the rinsing step.

In some embodiments, the method does not substantially remove a dielectric material (e.g., SiN, SiOx, or SiCO) in the semiconductor substrate. For example, the method does not remove more than about 5% by weight (e.g., more than about 3% by weight or more than about 1% by weight) of a metal conductor or a dielectric material in the semiconductor substrate.

In some embodiments, the etching method includes the steps of:
(A) providing a semiconductor substrate containing a Si film (e.g., a poly-Si film in a pattern or feature);
(B) contacting the semiconductor substrate with an etching composition described herein;
(C) rinsing the semiconductor substrate with one or more suitable rinse solvents; and
(D) optionally, drying the semiconductor substrate (e.g., by any suitable means that removes the rinse solvent and does not compromise the integrity of the semiconductor substrate).

The semiconductor substrates to be etched in this method can contain organic and organometallic residues, and a range of metal oxides, some or all of which may also be removed during the etching process.

Semiconductor substrates described herein (e.g., wafers) typically are constructed of silicon, silicon germanium, Group III-V compounds such as GaAs, or any combination thereof. The semiconductor substrates can additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, silicon, titanium nitride, tantalum nitride, and tungsten. The semiconductor substrates can also contain layers of interlayer dielectrics, polysilicon, silicon oxide, silicon nitride, silicon germanium, silicon carbide, titanium oxide, and carbon doped silicon oxides.

A semiconductor substrate can be contacted with the etching composition by any suitable method, such as placing the etching composition into a tank and immersing and/or submerging the semiconductor substrate into the etching composition, spraying the etching composition onto the semiconductor substrate, streaming the etching composition onto the semiconductor substrate, or any combinations thereof.

The etching composition of the present disclosure can be effectively used up to a temperature of about 85° C. (e.g., from about 50° C. to about 85° C., from about 60° C. to about 80° C., or from about 65° C. to about 75° C.). The etch rates of Si increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in an immersion batch type process, a suitable time range is, for example, up to about 10 minutes (e.g., from about 1 minute to about 7 minutes, from about 1 minute to about 5 minutes, or from about 2 minutes to about 4 minutes). Etching times for a single wafer process can range from about 30 seconds to about 60 minutes (e.g., from about 10 minutes to about 60 minutes, from about 20 minutes to about 60 minutes, or from about 30 minute to about 60 minutes).

To further promote the etching ability of the etching composition of the present disclosure, mechanical agitation means can be employed. Examples of suitable mechanical agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

Subsequent to the etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate, and propylene glycol monomethyl ether acetate. Alternatively, or in addition, aqueous rinses with pH>8 (such as dilute aqueous ammonium hydroxide) can be employed. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is between 16° C. and 27° C.

Optionally, the semiconductor substrate is dried after the rinsing step. Any suitable drying means known in the art can be employed. Examples of suitable drying means include spin drying, flowing a dry gas across the semiconductor substrate, or heating the semiconductor substrate with a heating means such as a hotplate or infrared lamp, Maragoni drying, rotagoni drying, IPA drying, and any combinations thereof. Drying times will be dependent on the specific method employed but are typically on the order of 30 seconds up to several minutes.

In some embodiments, the etching method described herein further includes forming a semiconductor device (e.g., an integrated circuit device such as a semiconductor chip) from the semiconductor substrate obtained by the method described above.

### EXAMPLES

### General Procedure 1

### Formulation Blending

Samples of etching compositions were prepared by adding, while stirring, to the calculated amount of the solvent the remaining components of the formulation.

### General Procedure 2

### Materials and Methods

Blanket film etch rate measurements on films were carried out using commercially available unpatterned 300 mm diameter wafers that were diced into 0.5″×1.0″ test coupons for evaluation. One half of the coupons were masked with PTFE (polytetrafluoroethylene) tape and etched in compositions of the disclosure for 30-60 minutes. The PTFE mask was removed after etching and a profilometer was used to measure the step height to calculate the etch rate of Si.

The test coupons were measured for pre-treatment and post-treatment thickness to determine blanket film etch rates. For the SiGe and HfOx blanket films, the film thicknesses were measured pre-treatment and post-treatment by Ellipsometry using a Woollam VASE. For W films, thickness was measured by a ResMap 4-point probe. SiGe and Si films were pretreated in dHF (dilute HF, 1:100) before being immersed in the compositions of the disclosure to remove native oxide on the surface.

### General Procedure 3

### Etching Evaluation with Beaker Test

All blanket film etch testing was carried out in a 150 ml PFA bottle containing 100 g of a sample solution with continuous stirring at 250 rpm. The PFA bottle was immersed into a 600 mL glass beaker filled with water serving as a water bath. The beaker was sitting on the top of a hot stirring plate set at the desired temperature. All blanket test coupons having a blanket film exposed on one side to the sample solution were diced by diamond scribe into 0.5″×1.0″ square test coupon size for beaker scale testing. Each individual test coupon was held into position using a single 4″ long, locking plastic tweezers clip. The test coupon, held on one edge by the locking tweezers clip, was suspended into the 150 ml PFA bottle and immersed into the 100 g test solution while the solution was stirred continuously at 250 rpm at 50° C. or 55° C. The test coupons were held static in the stirred solution until the treatment time (0.5 minutes or 60 minutes) had elapsed.

After the treatment time in the test solution had elapsed, the sample coupons were immediately removed from the 150 ml PFA bottle and rinsed. Specifically, the coupon was immersed in a 300 mL volume of ultra-high purity deionized (DI) water for seconds with mild agitation, which was followed by immersion in 300 mL of isopropyl alcohol (IPA) for 15 seconds with mild agitation, and a final rinse by immersion in 300 mL of IPA for 15 seconds with mild agitation. After the final IPA rinse step, all test coupons were subject to a filtered nitrogen gas blow off step using a hand held nitrogen gas blower which forcefully removed all traces of IPA to produce a final dry sample for test measurements.

### Example 1

Formulation Examples 1-12 were prepared according to General Procedure 1, and evaluated according to General Procedures 2 and 3. The formulation and test results are summarized in Tables 1 and 2. B-doped Si etch rates were measured after immersing a test coupon in a composition of the disclosure for 30 minutes at 55° C. and the SiGe, SiOx, HfOx, W, and TiN etch rates were measured after immersing a test coupon in a composition of the disclosure for 10 minutes at 55° C.

TABLE 1

| | Quat. | 2^{nd} | Organic | 1^{st} | | | | |
|---|---|---|---|---|---|---|---|---|
| Formulations | Ammon. | Amine | solvent | Amine | OPC | Water | Total | pH |
| FE-1 | TMAH | APDA | EG | DAMP | DPPA | 69.6% | 100% | 13.39 |
| | 6.18% | 0.05% | 5.12% | 19% | 0.05% | | | |
| FE-2 | TMAH | APDA | EG | DAMP | 0 | 69.65% | 100% | 13.67 |
| | 6.18% | 0.05% | 5.12% | 19% | | | | |
| FE-3 | 0 | APDA | EG | DAMP | 0 | 34.95% | 100% | 12.47 |
| | | 0.05% | 35% | 30% | | | | |
| CFE-1 | 0 | APDA | EG | HDA | 0 | 34.95% | 100% | 12.49 |
| | | 0.05% | 35% | 30% | | | | |
| FE-4 | TMAH | APDA | EG | HDA | 0 | 29.95% | 100% | 13.31 |
| | 5% | 0.05% | 35% | 30% | | | | |
| CFE-2 | 0 | APDA | EG | TMHDA | 0 | 34.95% | 100% | 12.26 |
| | | 0.05% | 35% | 30% | | | | |
| CFE-3 | 0 | APDA | EG | DAP | 0 | 34.95% | 100% | 12.67 |
| | | 0.05% | 35% | 30% | | | | |
| CFE-4 | 0 | APDA | EG | DETA | 0 | 79.95% | 100% | 11.98 |
| | | 0.05% | 5% | 15% | | | | |
| FE-5 | TMAH | APDA | DEGBE | DAMP | DPPA | 69.77% | 100% | 13.36 |
| | 6.18% | 0.05% | 5% | 19% | 0.05% | | | |
| FE-6 | ETMAH | APDA | EG | DAMP | 0 | 70.83% | 100% | 13.33 |
| | 5% | 0.05% | 5.12% | 19% | | | | |
| FE-7 | TBAH | APDA | EG | DAMP | 0 | 65.83% | 100% | 13.35 |
| | 10% | 0.05% | 5.12% | 19% | | | | |
| FE-8 | TMAH | APDA | EG | DAMP | MPA | 69.65% | 100% | 13.23 |
| | 6.18% | 0.05% | 5.12% | 19% | 0.05% | | | |

TMAH = tetramethylammonium hydroxide, ETMAH = ethyltrimethylammonium hydroxide, TBAH = tetrabutylammonium hydroxide, APDA = N-(3-aminopropyl)-diethanolamine, EG = ethylene glycol, DEGBE = diethyleneglycol monobutyl ether, DAMP = 1,5-diamino-2-methylpentane, HDA = 1,6-hexanediamine, TMHDA = trimethyl-1,6-hexanediamine, OPC = organophosphorus compound, DPPA = diphenylphosphinamide, MPA = methylphosphinic acid, DAP = 1,3-diaminopropane, DETA = diethylenetriamine, FE = formulation example, CFE = comparative formulation example

TABLE 2
Etch rates (Å/min)

| | | | p-EPI | | | | | Si/n-EPI | | |
|---|---|---|---|---|---|---|---|---|---|---|
| Formulation | Si | n-EPI Si | SiGe | SiOx | W | HfOx | TiN | Si | Si/SiGe | Si/SiOx |
| FE-1 60 C. | 2035 | 28 | 1.9 | 1.3 | 2.7 | | | 73 | 1071 | 1565 |
| FE-1 55 C. | 1054 | 17 | 0.3 | 0.6 | 2.2 | 0.1 | 0.6 | 62 | 3513 | 1757 |
| FE-1 50 C. | 634 | 13 | 0.3 | 0.6 | 1.5 | 0.1 | 0.3 | 49 | 2113 | 1057 |
| FE-2 | 631 | 17.6 | 0.8 | 0.8 | 1.4 | 0.1 | 0.2 | 36 | 789 | 789 |
| FE-3 | 359 | 14.9 | 4.8 | 0.1 | 2.7 | | | 24 | 75 | 3590 |
| CFE-1 | 347 | 15 | 6.3 | 1.2 | 2.6 | | | 23 | 55 | 289 |
| FE-4 | 368 | 45 | 5.6 | 1.3 | 2.9 | | | 8 | 66 | 283 |
| CFE-2 | 150 | 6 | 1.2 | 0.6 | 1.7 | | | 25 | 125 | 250 |
| CFE-3 | 520 | 119 | 7.4 | 0.5 | 2.6 | | | 4 | 70 | 1040 |
| CFE-4 | 739 | 55 | 7.9 | 5.5 | 2 | | | 13 | 94 | 134 |
| FE-5 | 705 | 16.8 | 0.6 | 0.4 | 2.3 | 0.1 | 0.3 | 42 | 1175 | 1763 |
| FE-6 | 631 | 17.6 | 1.5 | 0.8 | 1.4 | | | 36 | 421 | 789 |
| FE-7 | 180 | 17.8 | 2.4 | 1.3 | 1.1 | | | 10 | 75 | 138 |
| FE-8 | 595 | 16 | 1.5 | 0.8 | 2.1 | | | 37 | 397 | 744 |

As shown in Table 2, the formulations of the disclosure provide excellent Si etch rates as well as superb selective Si removal with respect to other layers typically found on a microelectronic device.

While the invention has been described in detail with reference to certain embodiments thereof, it will be understood that modifications and variations are within the spirit and scope of that which is described and claimed.

What is claimed is:

1. An etching composition, comprising:
at least one quaternary ammonium hydroxide;
at least one first amine;
at least one second amine different from the first amine, wherein the second amine comprises an amine of formula (I): N—R₁R₂R₃, wherein R₁ is C₁-C₈ alkyl optionally substituted by OH or NH₂, R₂ is H or C₁-C₈ alkyl optionally substituted by OH, and R₃ is C₁-C₈ alkyl optionally substituted by OH;
at least one organic solvent selected from water soluble alcohols, water soluble ketones, water soluble esters, and water soluble ethers; and
water.

2. The composition of claim 1, wherein the at least one quaternary ammonium hydroxide comprises tetramethylammonium hydroxide, tetraethylammonium hydroxide, or tetrabutylammonium hydroxide.

3. The composition of claim 1, wherein the at least one quaternary ammonium hydroxide is in an amount of from about 1 wt % to about 15 wt % of the composition.

4. The composition of claim 1, wherein the first amine is a diamine.

5. The composition of claim 4, wherein the diamine has a structure
NH₂—R—NH₂,
wherein R is a C₁ to C₁₀ straight chain or branched alkylene.

6. The composition of claim 5, wherein the diamine is 1,5-diamino-2-methylpentane, 1,6-hexanediamine, trimethyl-1,6-hexanediamine, or 1,3-diaminopropane.

7. The composition of claim 1, wherein the first amine is a triamine.

8. The composition of claim 7, wherein the triamine is diethylene triamine.

9. The composition of claim 1, wherein the first amine is in an amount of from about 10 wt % to about 40 wt % of the composition.

10. The composition of claim 1, wherein the second amine is an aminoalcohol.

11. The composition of claim 10, wherein the aminoalcohol is selected from monoethanolamine, diethanolamine, triethanolamine, 4-amino-1-butanol, 2-(2-aminoethoxy) ethanol, 3-amino-1-propanol, 2-amino-1-propanol, 1-amino-2-propanol, 2-amino-1-butanol, 2-amino-2-methyl 1-propanol, 2-(2-aminoethoxy) propanol, 5-amino-1-pentanol, 2-amino-1-pentanol, 2-amino-3-methyl-1-butanol, 2-amino-1-hexanol, isoleucinol, leucinol, 1-amino-1-cyclopentanemethanol, trans-2-aminocyclohexanol, trans-4-aminocyclohexanol, 3-aminomethyl-3,5,5-trimethylcyclohexanol, 1-aminomethyl-1-cyclohexanol, 6-amino-1-hexanol, 6-amino-2-methyl-2-heptanol, 4-amino-4-(3-hydroxypropyl)-1,7-heptanediol, serinol, 3-amino-1,2-propanediol, N-(3-aminopropyl)-diethanolamine, 2-amino-2-ethyl-1,3-propanediol, 2-amino-2-methyl-1,3-propanediol, tris (hydroxymethyl)-aminomethane, 1-amino-1-deoxy-D-sorbitol, (hydroxyethoxyethyl) amine, 4-amino-1-butanol, 2-(2-aminoethoxy) ethanol, ethanolamine, 3-amino-1-propanol, 2-amino-1-propanol, 1-amino-2-propanol, 2-amino-1-butanol, 2-amino-2-methyl 1-propanol, 2-(2-aminoethoxy) propanol, 5-amino-1-pentanol, 2-amino-1-pentanol, 2-amino-3-methyl-1-butanol, 2-amino-1-hexanol, isoleucinol, leucinol, 1-amino-1-cyclopentanemethanol, trans-2-aminocyclohexanol, trans-4-aminocyclohexanol, 3-aminomethyl-3,5,5-trimethylcyclohexanol, 1-aminomethyl-1-cyclohexanol, 6-amino-1-hexanol, and 6-amino-2-methyl-2-heptanol.

12. The composition of claim 1, wherein the second amine is in an amount of from about 0.01 wt % to about 0.5 wt % of the composition.

13. The composition of claim 1, further comprising at least one organophosphorus compound.

14. The composition of claim 13, wherein the organophosphorus compound is a phosphinamide.

15. The composition of claim 14, wherein the phosphinamide is diphenylphosphinamide.

16. The composition of claim 1, wherein the organophosphorus compound is in an amount of from about 0.01 wt % to about 0.5 wt % of the composition.

17. The composition of claim 1, wherein the organic solvent is an alkylene glycol.

18. The composition of claim 17, wherein the alkylene glycol is ethylene glycol, propylene glycol, diethylene glycol, dipropylene glycol, triethylene glycol or tetraethyleneglycol.

19. The composition of claim 1, wherein the organic solvent is an alkylene glycol ether.

20. The composition of claim 19, wherein the alkylene glycol ether is selected from ethylene glycol monomethyl ether, ethylene glycol monoethyl ether, ethylene glycol mono n-propyl ether, ethylene glycol monoisopropyl ether, ethylene glycol mono n-butyl ether, diethylene glycol monomethyl ether, diethylene glycol monoethyl ether, diethylene glycol monobutylether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

21. The composition of claim 1, wherein the organic solvent is in an amount of from about 2 wt % to about 40 wt %.

22. The composition of claim 1, wherein the composition has a pH from about 11 to about 14.

23. The composition of claim 1, wherein the water is in an amount of from about 25 wt % to about 80 wt % of the composition.

24. A method, comprising:
contacting a semiconductor substrate containing a Si film with a composition of claim 1 to substantially remove the Si film.

25. The method of claim 24, wherein the method does not substantially remove silicon oxide or silicon nitride.

26. A method comprising:
(A) providing a semiconductor substrate containing a Si film;
(B) contacting the semiconductor substrate with an etching composition of claim 1;
(C) rinsing the semiconductor substrate with one or more suitable rinse solvents; and
(D) optionally, drying the semiconductor substrate.

27. An article formed by the method of claim 24, wherein the article is a semiconductor device.

28. The article of claim 27, wherein the semiconductor device is an integrated circuit.
